(19) United States
(12) Patent Application Publication
(10) Pub. No.: US 2010/0240196 A1
(43) Pub. Date: Sep. 23, 2010

(54) ADHESIVE, ADHESIVE SHEET, MULTI-LAYERED ADHESIVE SHEET, AND PRODUCTION METHOD FOR AN ELECTRONIC PART

(76) Inventors: Takeshi Saito, Gunma (JP); Tomomichi Takatsu, Gunma (JP)

Correspondence Address: STEIN MCEWEN, LLP, 1400 EYE STREET, NW, SUITE 300, WASHINGTON, DC, 20005, US

(21) Appl. No.: 12/682,909

(22) PCT Filed: Oct. 16, 2007
(86) PCT No.: PCT/JP2007/070166

§ 371 Date: Apr. 14, 2010

(51) Int. Cl. H01L 21/78; C09J 133/12; B32B 27/36

(52) U.S. Cl. 438/464; 525/123; 428/355 CN; 428/354; 257/E21.599

(57) ABSTRACT

A multi-layered adhesive sheet includes a substrate film, an adhesive layer formed by coating an adhesive having a specific composition onto the substrate film, and a die attachment film laminated on the adhesive layer. The multi-layered adhesive sheet employing an adhesive having this specific composition is superior in retention of a die chip during dicing of a silicon wafer, the multi-layered adhesive sheet is less likely to come off a ring frame during the dicing of the silicon wafer, and it allows for the die attachment film and the adhesive layer to be easily peeled apart during a pick-up operation of a die chip.

### CROSS-REFERENCE TO RELATED APPLICATION

This application claims the benefit of PCT International Patent Application No. PCT/JP2007/070166, filed Oct. 16, 2007, the disclosure of which is incorporated herein by reference.

### BACKGROUND OF THE INVENTION

1. Field of the Invention

The present invention relates to an adhesive, an adhesive sheet, a multi-layered adhesive sheet, and a production method for an electronic part.

2. Description of the Related Art

As a production method for an electronic part, a method is known in which an electronic parts assembly is made by forming a plurality of circuit patterns on an insulating substrate or a wafer, then the electronic parts assembly is processed into chips, the chips are picked-up, an adhesive agent is coated onto a bottom surface of the chips, the chips are fixed to a lead frame or the like via the adhesive agent, and the chips are sealed via a resin or the like, so as to form the electronic part (see Non-Patent Document 1).

As a method of processing the electronic parts assembly into chips, a method is known in which the electronic parts assembly is pasted to an adhesive sheet, and then separation by cutting (dicing) it into individual chips is performed after the adhesive sheet is fixed to a ring frame.

A method of employing a multi-layered adhesive sheet (die attachment film all-in-one sheet) providing the combined functions of an adhesive agent that fixes a chip to a lead frame or the like, with that of an adhesive sheet for dicing, via the lamination of an adhesive sheet and a die attachment film, has been proposed (see Patent Documents 1 to 4).

By employing the die attachment film all-in-one sheet in the production of an electronic part, a coating process of an adhesive agent can be omitted after dicing. When compared to a method using an adhesive agent in the attachment of a chip and a lead frame, the die attachment film all-in-one sheet is superior in that it is capable of controlling thickening of the adhered portions or preventing oozing. A die attachment film all-in-one sheet has been utilized in the production of electronic part, such as a chip size package, a stack package, and a system-in-a-package.
Patent Document 1: JP-A 2004-186429;
Patent Document 2: JP-A 2006-049509;
Patent Document 3: JP-A H02-248064;
Patent Document 4: JP-A H05-211234; and
Non-Patent Document 1: T. Ozawa et al., Furukawa Review, No. 106, p 31, Furukawa Electric Co. Ltd. (July, 2000).

### DISCLOSURE OF THE INVENTION

### Problems to be Solved by the Invention

However, an acrylic adhesive is employed for a general pressure-sensitive type among the die attachment film all-in-one sheets; therefore, in the case where a normal acrylic adhesive is employed, there are instances where when the adhesiveness of the adhesive sheet and the ring frame becomes low, the adhesive sheet and the ring frame are peeled apart during dicing, or instances where a pick-up defect occurs in which the adhesive sheet and the die attachment film are not peeled apart at an interface thereof during pick-up.

Moreover, along with the higher integration of semiconductor parts, chip sizes have gotten considerably thinner, and cases in which pick-up operations of chips have become difficult after dicing have increased. Accordingly, a die attachment film all-in-one sheet that provides the features of superior chip retention during dicing, and easily allowing for the die attachment film and the adhesive sheet to be peeled apart during pick-up has been needed.

The present invention was achieved in view of the abovementioned problems, and thus an object thereof is to provide technology for superior chip retention during dicing and for easily allowing for the die attachment film and the adhesive sheet to be peeled apart during pick-up, while performing the dicing of the wafer by employing the die attachment film all-in-one sheet.

### Means for Solving the Problems

According to the present invention, an adhesive comprising 100 parts by mass of an acrylic polymer and at least 0.5 parts by mass to no more than 20 parts by mass of a polyfunctional isocyanate curing agent is proposed, in which the acrylic polymer is formed by polymerization of a raw material composition obtained by compounding at least 90 parts by mass to no more than 99.9 parts by mass of a (meth)acrylic acid alkyl ester monomer having an alkyl group with at least 6 carbon atoms to no more than 12 carbon atoms, and at least 0.1 parts by mass to no more than 10 parts by mass of a functional group-containing monomer.

A die attachment film all-in-one sheet employing the adhesive comprising the abovementioned composition is superior in chip retention during dicing, is less likely to come off from a ring frame during dicing, and allows for easy peeling of the chip during a pick-up operation. Therefore, the adhesive may be preferably employed in an adhesive layer of the die attachment film all-in-one sheet.

Moreover, in the present invention, the abovementioned adhesive may further comprise a compound having at least one (meth)acryloyl group.

Because the adhesiveness of the die attachment film and the adhesive sheet is further improved by having the abovementioned adhesive further contain a compound having at least one (meth)acryloyl group, the chip retention is further improved during dicing, and the peeling apart of the adhesive sheet and the ring frame during dicing is further prevented.

Furthermore, according to the present invention, an adhesive sheet is provided which includes: a substrate film, and an adhesive layer formed by coating the adhesive onto the substrate film.

The abovementioned die attachment film all-in-one sheet employing the adhesive sheet having the abovementioned construction is superior in chip retention during dicing, is less likely to come off from the ring frame during dicing, and allows for easy peeling of the chip during a pick-up operation. Accordingly, this adhesive sheet may be preferably employed as the adhesive sheet of the die attachment film all-in-one sheet.

In addition, according to the present invention, a multi-layered adhesive sheet is provided which includes: the abovementioned adhesive sheet, and a die attachment film laminated on an adhesive layer side of the adhesive sheet.

In cases where the multi-layered adhesive sheet having the abovementioned construction is employed as the die attachment film all-in-one sheet, it is superior in chip retention during dicing, it is less likely to come off from the ring frame during dicing, and it allows for easy peeling of the chip during the pick-up operation. Accordingly, this multi-layered adhesive sheet may be preferably employed as the die attachment film all-in-one sheet.

Moreover, according to the present invention, a production method for an electronic part obtained by dicing a wafer is provided which includes steps of: pasting a wafer on a surface of the die attachment film of the abovementioned multi-layered adhesive sheet; dicing the wafer with it pasted to the multi-layered adhesive sheet; and picking-up both the wafer and the die attachment film attached to a rear surface of the wafer, by peeling apart the die attachment film and the abovementioned adhesive layer after the dicing.

The multi-layered adhesive sheet employed in the abovementioned production method for the electronic part is superior in chip retention during dicing, is less likely to come off from a ring frame during dicing, and allows for easy peeling between the die attachment film and the adhesive layer during the pick-up operation. Thus, the abovementioned production method for the electronic part allows for the pick-up of the chip with the die attachment film attached to a rear surface of the chip after dicing, and the chip to be mounted and bonded as is on a lead frame or the like.

### Effects of the Invention

According to the present invention, because an adhesive having a specific composition is employed, it allows for superior chip retention during dicing, it is less likely to come off from a ring frame during dicing, and it allows for easy peeling of a chip during a pick-up operation, when performing dicing of a wafer by employing a die attachment film all-in-one sheet.

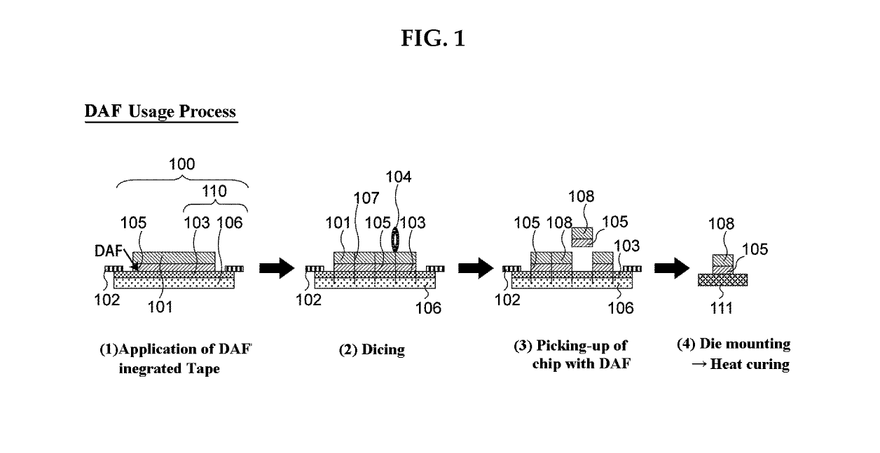

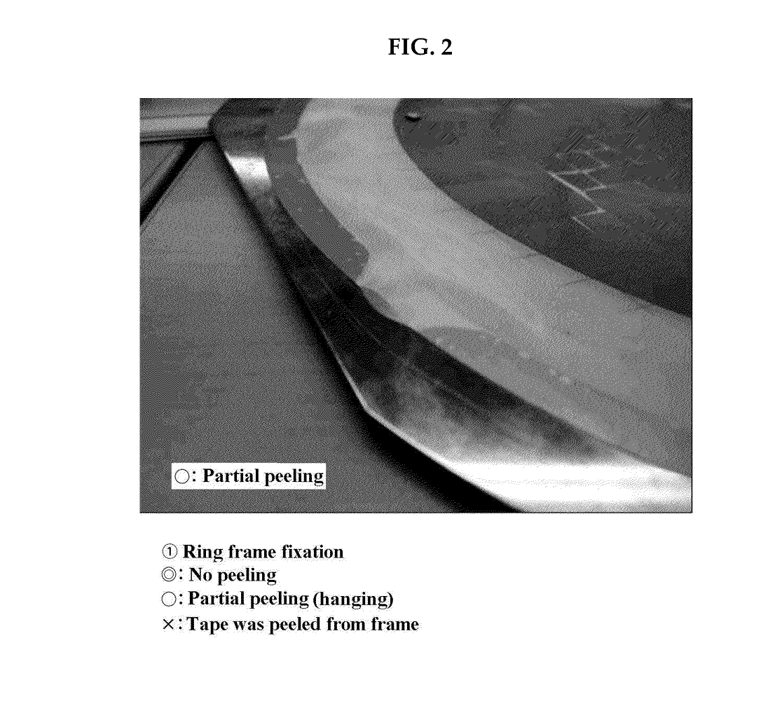

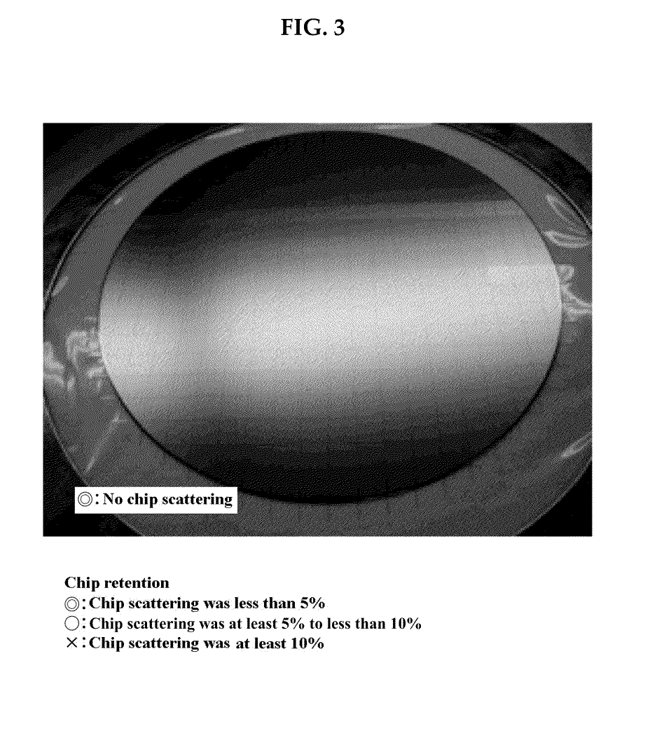

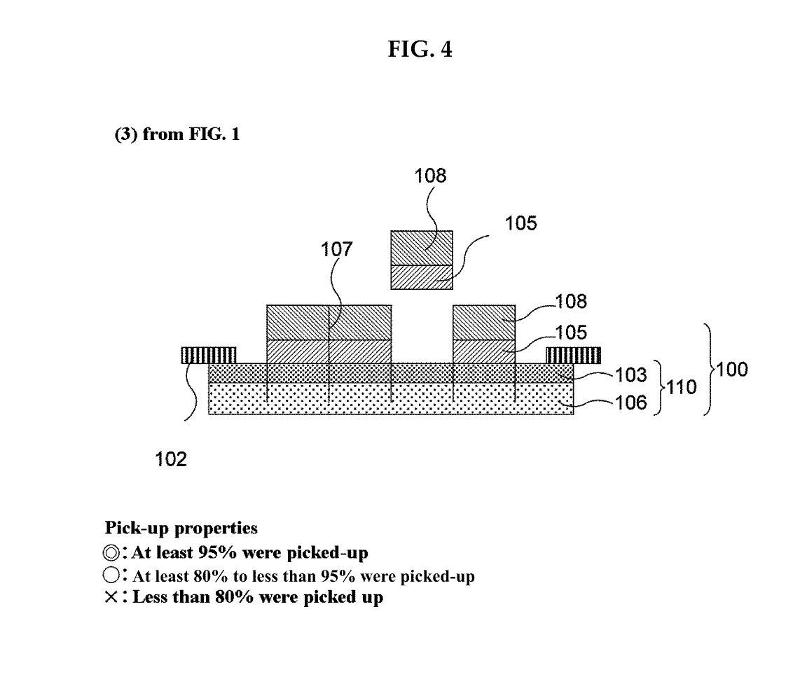

### BRIEF DESCRIPTION OF THE DRAWINGS

[FIG. 1] A schematic diagram showing cross-sectional view for describing a structure of a multi-layered adhesive sheet of one embodiment.

[FIG. 2] A photograph for describing ring frame fixation.

[FIG. 3] A photograph for describing chip retention.

[FIG. 4] A schematic diagram for describing a pick-up property.

### EXPLANATION OF THE REFERENCE NUMERALS

100 multi-layered pressure-sensitive adhesive sheet

101 silicon wafer

102 ring frame

103 adhesive layer

104 dicing blade

105 die attachment film

106 substrate film

107 incision

108 die chip

110 adhesive sheet

111 lead frame

### PREFERRED MODE FOR CARRYING OUT THE INVENTION

Hereinafter, embodiments of the present invention will be described with reference to the drawings. However, in cases where the same constituents are appended with the same reference numerals in each of the drawings, duplicate descriptions thereof will be omitted.

### <Description of the Terms>

In the present specification, “monomer” refers to the so-called monomers per se or the structures derived from monomers. Unless specifically stated otherwise, “parts” and “%” of the present specification refers to a mass basis. In the present specification, a (meth)acryloyl group is a generic term for an acryloyl group and a methacryloyl group. The same also holds true for a compound including a (meth) such as (meth)acrylic acid and the like, in which the generic term is for a compound that does not include “meth” in the name and a compound that does include “meth” in the name.

### Brief Overview of the Embodiments

FIG. 1 is a cross-sectional view describing a structure of a multi-layered adhesive sheet of the present embodiment.

As shown in FIG. 1(1), a multi-layered adhesive sheet (die attachment film all-in-one sheet) 100 of the present embodiment includes a substrate film 106, an adhesive layer 103 formed by coating the below-described adhesive onto this substrate film 106, and a die attachment film 105 laminated on this adhesive layer 103.

An adhesive sheet 110 refers to a sheet formed by combining the abovementioned substrate film 106 with the adhesive layer 103 formed by coating below-described adhesive onto the substrate film 106. Specifically, the multi-layered sheet 100 includes the adhesive sheet 110, and the die attachment film 105 laminated on the adhesive layer 103 side of this adhesive sheet 110.

In addition, the abovementioned adhesive layer 103 is formed by coating an adhesive on the substrate film 106, the adhesive containing 100 parts by mass of an acrylic polymer and at least 0.5 parts by mass to no more than 20 parts by mass of a polyfunctional isocyanate curing agent, in which the acrylic polymer is formed by polymerization of a raw material composition obtained by compounding at least 90 parts by mass to no more than 99.9 parts by mass of a (meth)acrylic acid alkyl ester monomer having an alkyl group with at least 6 carbon atoms to no more than 12 carbon atoms, and at least 0.1 parts by mass to no more than 10 parts by mass of a functional group-containing monomer.

The multi-layered adhesive sheet (die attachment film all-in-one sheet) 100 employing the adhesive having the abovementioned construction is superior in retention of a die chip 108 during dicing of a silicon wafer 101, it is less likely that the multi-layered adhesive sheet 100 will come off from a ring frame 102 during dicing of the silicon wafer 101, and it easily allows for the peeling apart of the die attachment film 105 and the adhesive layer 103 during the pick-up operation of the die chip 108.

Moreover, the abovementioned adhesive may further contain a compound having at least one (meth)acryloyl group. Because the adhesiveness of the die attachment film 105 and the adhesive sheet 110 is further improved by having the abovementioned adhesive further contain a compound having at least one (meth)acryloyl group, the chip retention is further improved during dicing, and the peeling apart of the adhesive sheet 110 and the ring frame 102 is further prevented.

Thus, the production method for the electronic part employing this multi-layered adhesive sheet 100 allows for the pick-up of the die chip 108 with the die attachment film 105 attached to a rear surface of the die chip 108 after dicing of the silicon wafer 101, and the die chip 108 to be mounted and bonded as is on a lead frame 111 or the like.

### <Adhesive Layer>

As the adhesive layer 103, an adhesive containing 100 parts by mass of an acrylic polymer, and at least 0.5 parts by mass to no more than 20 parts by mass of a polyfunctional isocyanate curing agent is employed. In such a case, the abovementioned acrylic polymer that is used is polymerized from a raw material composition obtained by compounding at least 90 parts by mass to no more than 99.9 parts by mass of a (meth)acrylic acid alkyl ester monomer having an alkyl group with at least 6 carbon atoms to no more than 12 carbon atoms, and at least 0.1 parts by mass to no more than 10 parts by mass of a functional group containing monomer.

The multi-layered adhesive sheet (die attachment film all-in-one sheet) 100 employing the adhesive having the abovementioned construction is superior in retention of a die chip 108 during dicing of a silicon wafer 101, it is less likely that the multi-layered adhesive sheet 100 will come off from the ring frame 102 during dicing of the silicon wafer 101, and it easily allows for the peeling apart of the die attachment film 105 and the adhesive layer 103 during the pick-up operation of the die chip 108.

As the (meth)acrylic acid alkyl ester monomer having an alkyl group with at least 6 carbon atoms to no more than 12 carbon atoms, hexyl acrylate, n-octyl acrylate, isooctyl acrylate, 2-ethylhexyl acrylate, dodecyl acrylate, decyl acrylate and so on may be exemplified. Because the adhesive strength of the adhesive layer 103 and the ring frame 102 is increased when employed, 2-ethylhexyl acrylate is preferable among the (meth)acrylic acid alkyl ester monomers.

By employing the (meth)acrylic acid alkyl ester monomer having an alkyl group with at least 6 carbon atoms to no more than 12 carbon atoms, along with improving the chip retention during dicing, the peeling apart of the adhesive sheet 110 and the ring frame 102 during a the dicing operation can be further prevented.

As the functional group-containing monomer, a monomer having a hydroxyl group, a carboxyl group, an epoxy group, an amide group, an amino group, a methylol group, a sulphonic acid group, a sulfamic acid group, or a phosphite ester group as the functional group may be exemplified, with a monomer having a hydroxyl group being preferable. Hereinafter, examples of the functional group-containing monomer will be provided.

As the monomer having the hydroxyl group, 2-hydroxyethyl(meth)acrylate, 2-hydroxypropyl(meth)acrylate, and 2-hydroxybutyl(meth)acrylate may be exemplified.

As the monomer having the carboxyl group, (meth)acrylic acid, crotonic acid, maleic acid, anhydrous maleic acid, itaconic acid, fumaric acid, acrylamido-N-glycolic acid, and cinnamic acid may be exemplified.

As the monomer having the epoxy group, allyl glycidyl ether and (meth)acrylic acid glycidyl ether may be exemplified.

As the monomer having the amide group, (meth)acrylamide may be exemplified.

As the monomer having the amino group, N,N-dimethyl aminoethyl(meth)acrylate may be exemplified.

As the monomer having the methylol group, N-methylol acrylamide may be exemplified.

In addition to the (meth)acrylic acid alkyl ester monomer having an alkyl group with at least 6 carbon atoms to no more than 12 carbon atoms, the acrylic polymer may also include a (meth)acrylic acid ester monomer having an alkyl group of less than 6 carbon atoms or greater than 12 carbon atoms. As such a (meth)acrylic acid alkyl ester monomer, methyl(meth)acrylate, ethyl(meth)acrylate, isopropyl(meth)acrylate, butyl(meth)acrylate, 2-methoxyethyl acrylate, and isobonyl(meth)acrylate may be exemplified.

The acrylic polymer may employ vinyl monomers other than those described above. Thus, a vinyl compound such as ethylene, styrene, vinyl toluene, allyl acetate, vinyl propionate, vinyl butyrate, vinyl versate, vinyl ethyl ether, vinyl propyl ether, (meth)acrylonitrile, and vinyl isobutyl ether may be exemplified.

The polyfunctional isocyanate curing agent is not particularly limited in any way, so long as it has at least two isocyanate groups. Thus, aromatic polyisocyanate, aliphatic polyisocyanate, and alicyclic polyisocyanate may be exemplified.

The aromatic polyisocyanate is not particularly limited in any way. Thus, 1,3-phenylene diisocyanate; 4,4′-diphenyl diisocyanate; 1,4-phenylene diisocyanate; 4,4′-diphenylmethane diisocyanate; 2,4-tolylene diisocyanate; 2,6-tolylene diisocyanate; 4,4′-toluidine diisocyanate; 2,4,6-triisocyanate toluene; 1,3,5-triisocyanate benzene; dianisidine diisocyanate; 4,4′-diphenylether diisocyanate; 4,4′,4″-triphenylmethane triisocyanate; ω,ω′-diisocyanate-1,3-dimethyl benzene; ω,ω′-diisocyanate-1,4-dimethyl benzene; ω,ω′-diisocyanate-1,4-diethyl benzene; 1,4-tetramethylxylylene diisocyanate; and 1,3-tetramethylxylylene diisocyanate may be exemplified.

The aliphatic polyisocyanate is not particularly limited in any way. Thus, trimethylene diisocyanate; tetramethylene diisocyanate; hexamethylene diisocyanate; pentamethylene diisocyanate; 1,2-propylene diisocyanate; 2,3-butylene diisocyanate; 1,3-butylene diisocyanate; dodecamethylene diisocyanate; and 2,4,4-trimethyl hexamethylene diisocyanate may be exemplified.

The alicyclic polyisocyanate is not particularly limited in any way. Thus, 3-isocyanatomethyl-3,5,5-trimethyl cyclohexyl isocyanate; 1,3-cyclopentane diisocyanate; 1,3-cyclohexane diisocyanate; 1,4-cyclohexane diisocyanate; methyl-2,4-cyclohexane diisocyanate; methyl-2,6-cyclohexane diisocyanate; 4,4′-methylenebis(cyclohexyl isocyanate); and 1,4-bis(isocyanatomethyl)cyclohexane may be exemplified.

Among the polyisocyanates, 1,3-phenylene diisocyanate, 4,4′-diphenyl diisocyanate, 1,4-phenylene diisocyanate, 4,4′-diphenylmethane diisocyanate, 2,4-tolylene diisocyanate, 2,6-tolylene diisocyanate, and 4,4′-toluidine diisocyanate are the readily available aromatic polyisocyanates that are preferably employed.

Because the adhesiveness of the die attachment film 105 and the adhesive sheet 110 is further improved when a compound having at least one (meth)acryloyl group is also contained in the adhesive, the chip retention is further improved during dicing, and the peeling apart of the adhesive sheet 110 and the ring frame 102 is further prevented, and thus it is preferable.

As the compound having at least one (meth)acryloyl group, it is preferable that the compound having at least one (meth)acryloyl group is intramolecularly incorporated into the monomer compound. Thus, butyl(meth)acrylate, pentyl(meth)acrylate, octyl(meth)acrylate, 2-ethylhexyl(meth)acrylate, nonyl(meth)acrylate, decyl(meth)acrylate, lauryl(meth)acrylate, methyl(meth)acrylate, ethyl(meth)acrylate, isopropyl(meth)acrylate, tridecyl(meth)acrylate, myristyl(meth)acrylate, cetyl(meth)acrylate, stearyl(meth)acrylate, cyclohexyl(meth)acrylate, benzyl(meth)acrylate, 2-hydroxyethyl(meth)acrylate, 2-hydroxypropyl(meth)acrylate, 2-hydroxybutyl(meth)acrylate, (meth)acrylic acid, and crotonic acid may be exemplified.

A compounding ratio of the polyfunctional isocyanate curing agent is preferably at least 0.5 parts by mass with respect to 100 parts by mass of an acrylic adhesive, and more preferably at least one part by mass. On the other hand, the compounding ratio of the polyfunctional isocyanate curing agent is preferably no more than 20 parts by mass with respect to 100 parts by mass of the acrylic adhesive, and more preferably no more than 10 parts by mass. Because the adhesiveness is not too strong when the polyfunctional isocyanate curing agent is at least 0.5 parts by mass or at least one part by mass, the occurrence of pick-up defects can be prevented. When the polyfunctional isocyanate curing agent is no more than 20 parts by mass or no more than 10 parts by mass, the advantages are that adhesiveness is improved, chip retention between the adhesive layer 103 and the die attachment film 105 during dicing is improved, and it is less likely that the adhesive layer 103 and the ring frame 102 will be peeled apart during the dicing operation.

In a case where the compound having at least one (meth)acryloyl group is employed, it is preferable that the compound having at least one (meth)acryloyl group is no more than 0.1 parts by mass with respect to 100 parts by mass of the acrylic polymer, and more preferably no more than 0.05 parts by mass. Moreover, although there are no particular limitations regarding the lower limits thereof, for example, at least 0.005 parts by mass is preferable, with at least 0.01 parts by mass being even more preferable.

When the compound having at least one (meth)acryloyl group is added in no more than 0.1 parts by mass or no more than 0.05 parts by mass, the adhesiveness of the die attachment film 105 is improved, and fixation defects occurring when molding the die chip 108 via a resin (not shown) can be prevented. On the other hand, when the compound having at least one (meth)acryloyl group is added in at least 0.005 parts by mass or at least 0.01 parts by mass, the adhesiveness of the die attachment film 105 and the adhesive layer 103 is improved, the chip retention during dicing is improved, and the peeling apart of the adhesive layer 103 and the ring frame 102 is prevented, and thus it is preferable.

A thickness of the adhesive layer 103 is preferably at least 1 μm, with a thickness of at least 3 μm being especially preferable. Furthermore, the thickness of the adhesive layer 103 is preferably no more than 100 μm, with a thickness of no more than 40 μm being especially preferable. So long as the thickness of the adhesive layer 103 is no more than 100 μm or no more than 40 μm, the die chip 108 can be suitably picked-up, and the occurrence of chipping of the end portion of the die chip 108, referred to as “chipping”, can be prevented. Moreover, when the thickness of the adhesive layer 103 is at least 1 μm or at least 3 μm, in addition to the chip being sufficiently retained during dicing, the peeling apart of the ring frame 102 and the multi-layered adhesive sheet 100 can be prevented.

Moreover, various additives such a softening agent, an anti-aging agent, a bulking agent, a thermal polymerization inhibitor, and the like may also be added to the adhesive layer 103 where appropriate.

### <Adhesive Sheet>

The adhesive sheet 110 including the substrate film 106 and the adhesive layer 103 formed on this substrate film 106 is produced by coating the adhesive on substrate film 106. The thickness of the substrate film 106 is preferably at least 30 μm to no more than 300 μm, and more preferably at least 60 μm to no more than 200 μm.

The substrate film 106 is available as a sheet made of various synthetic resins. The raw material of the substrate film 106 is not particularly limited in any manner. Thus, polyvinyl chloride, polyethylene terephthalate, ethylene-vinyl acetate copolymer, ethylene-ethylacrylate copolymer, polyethylene, polypropylene, ethylene-acrylic acid copolymer, and ionomer resin may be exemplified. A mixture, a copolymer and a multi-layered film or the like of these resins may be also be used in the substrate film 106.

Preferably, an ionomer resin is employed as a raw material of the substrate film 106. Even among ionomer resins, an ionomer resin in which a copolymer having ethylene units, (meth)acrylic acid units and (meth)acrylic acid alkyl ester units crosslinked with metal ions such as Na⁺, K⁺ and Zn²⁺, demonstrates the remarkable effect of preventing the generation of beard shaped cutting debris, and thus it is preferably employed.

A forming method of the substrate film 106 is not particularly limited in any manner. Thus, calendar forming, T-die extrusion, inflation, and casting may be exemplified.

With regard to the substrate film 106, in order to prevent an electrostatic charge during the peeling of the die attachment film 105, an antistatic treatment may be executed by coating an anti-electrostatic agent on one or both surfaces of the substrate film 106.

As the anti-electrostatic agent, a quaternary amine salt monomer is preferably employed. As the quaternary amine salt monomer, quaternary dimethylaminoethyl(meth)acrylate chloride, quaternary diethylaminoethyl(meth)acrylate chloride, quaternary methylethylaminoethyl(meth)acrylate chloride, quaternary p-dimethylaminostyrene chloride, and quaternary p-diethylaminostyrene chloride may be exemplified, with quaternary dimethylaminoethyl(meth)acrylate chloride being preferably employed.

A method of use of the anti-electrostatic agent and a lubricant is not particularly limited in any manner. For example, an adhesive may be coated onto one side of the substrate film 106, and the lubricant and/or the anti-electrostatic agent may be coated onto a rear surface thereof; or the lubricant and/or the anti-electrostatic agent may be formed into a sheet by being kneaded into the resin of the substrate film 106.

The die attachment film 105 is laminated onto the adhesive layer 103 on one side of the substrate film 106, which allows the other surface of the substrate film 106 to be an embossed surface with an average surface roughness (Ra) of at least 0.3 μm to no more than 1.5 μm. By placing the embossed surface on a machine table side of an expansion device (not shown), the substrate film 106 can be easily expanded via an expansion process after dicing.

The lubricant can be applied to a surface of the substrate film 106 that makes contact (a rear surface of the substrate film 106) with the expansion device (not shown), and the lubricant can be kneaded into the substrate film 106, in order to further improve the expansion properties after dicing.

The lubricant is not particularly limited in any particular manner, so long as the material reduces the coefficient of friction between the substrate film 106 and the expansion device (not shown). Thus, a silicone compound such as silicone resin or (modified) silicone oil; fluororesin; hexagonal boron nitride; carbon black; and molybdenum disulfide may be exemplified. In these lubricants, a plurality of ingredients may be mixed. Because the production method for the electronic part is conducted in a clean room, it is preferable that a silicone compound or fluororesin is employed as the lubricant. Even among silicone compounds, a copolymer in which a silicone graft monomer is copolymerized demonstrates a particularly high degree of compatibility with an anti-electrostatic charge layer, and thus is preferably employed to balance the expansion properties and the electrostatic charge properties.

It is preferable that an arithmetic mean Ra of a surface of the adhesive sheet 110 that is making contact with the die attachment film 105 (the surface of the adhesive layer 103) is at least 0.5 μm to no more than 1.5 μm, in order to improve the peelability of the adhesive layer 103 and the die attachment film 105.

A mold-release treatment may be performed on a surface of the adhesive sheet 110 that is making contact with the die attachment film of 105 (the surface of the adhesive layer 103), in order to allow for the easy peeling apart of the adhesive layer 103 and the die attachment film 105. A mold-release agent such as alkyd resin, silicone resin, fluororesin, unsaturated polyester resin, and wax may be employed in this mold-release treatment.

The method for forming the adhesive sheet 110 by forming the adhesive layer 103 on the substrate film 106 is not particularly limited in any manner. For example, a method of directly coating the adhesive on the substrate film via a coater such as a gravure coater, a comma coater, a bar coater, a knife coater, or a roll coater may be exemplified. The adhesive may also be printed on the substrate film via relief printing, intaglio printing, lithographic printing, flexographic printing, offset printing, or screen printing. Although the thickness of the adhesive layer 103 is not particularly limited in any way, a post-drying thickness of at least 1 μm to no more than 100 μm is preferable, with a post-drying thickness of at least 3 μm to no more than 40 μm being even more preferable.

### <Die Attachment Film>

The die attachment film 105 is composed of an adhesive or a pressure-sensitive adhesive formed into a film shape. The die attachment film 105 is commercially available as an adhesive or a pressure-sensitive adhesive laminated on a release film or the like that is composed of a PET resin or the like, and the adhesive or the pressure-sensitive adhesive can be transferred to the adhesive sheet.

The material of the die attachment film 105 may be any component of an adhesive or adhesive agent that is typically used. As the adhesive, epoxy, polyamide, acrylic, and polyimide may be exemplified. As the pressure-sensitive adhesive, acrylic, vinyl acetate, ethylene-vinyl acetate copolymer, ethylene-acrylic acid ester copolymer, polyamide, polyethylene, polysulfone, epoxy, polyimide, polyamide acid, silicone, phenol, rubber polymer, fluororubber polymer, and fluororesin may be exemplified.

Moreover, a mixture, a copolymer and a laminate of these may also be employed as the pressure-sensitive adhesive or adhesive in the die attachment film 105. An additive, such as a photopolymerization initiator, an anti-electrostatic agent, and a crosslinking promoter may also be compounded into the die attachment film 105, where necessary. Although the thickness of the die attachment film 105 is at least 5 μm to no more than 60 μm, preventing oozing from a surface or controlling thickening of the die attachment film during attachment of the chip and the lead frame is preferable.

### <Multi-Layered Adhesive Sheet>

The die attachment film 105 all-in-one sheet is pasted onto an adhesive coating surface of the adhesive sheet 110 to form the multi-layered adhesive sheet 100. In a case where employing the multi-layered adhesive sheet 100 as the die attachment film 105 used in the production method of the electronic part, it is preferable that a ratio of the acrylic adhesive and the polyfunctional isocyanate is controlled so that the adhesive strength between the die attachment film 105 and the adhesive sheet 110 is at least 0.05 N/20 mm to no more than 0.9 N/20 mm. The advantages are that when the adhesive strength between the die attachment film 105 and the adhesive sheet 110 is no more than 0.9 N/20 mm the occurrence of pick-up defects is prevented; and when the adhesive strength is at least 0.05 N/20 mm, the chip retention is improved, while simultaneously making the peeling apart of the adhesive sheet 110 and the ring frame 102 less likely.

As the method of controlling the adhesive strength between the die attachment film 105 and the adhesive sheet 110, a method of adding a tackifying resin to the adhesive may be exemplified. The tackifying resin is not particularly limited in any way. Thus, rosin resin, rosin ester resin, terpene resin, terpene phenol resin, phenol resin, xylene resin, cumarone resin, cumarone-indene resin, styrene resin, aliphatic petroleum resin, aromatic petroleum resin, aliphatic aromatic copolymer petroleum resin, alicyclic hydrocarbon resin, as well as a modified product thereof, a derivative thereof, or a hydrogenated product thereof may be exemplified.

Although the compounding amount of the tackifying resin is not particularly limited in any manner, no more than 200 parts by mass is preferable, with no more than 30 parts by mass being optimal with respect to 100 parts by mass of (meth)acrylic acid ester polymer.

### <Production Method for Electronic Part>

The production method for the electronic part employing the multi-layered adhesive sheet 100 of the present embodiment is not particularly limited in any manner, and thus the below-mentioned procedure indicated in FIG. 1 may be exemplified.
(1) The silicon wafer 101 is attached and fixed to the multi-layered adhesive sheet 100, and the multi-layered adhesive sheet 100 is then fixed to the ring frame 102.
(2) The silicon wafer 101 is diced with the dicing blade 104.
(3) The interval of the die chip 108 is broadened by radially expanding the multi-layered adhesive sheet 100, and afterwards the die chip 108 is pressed up with a needle or the like (not shown). Next, the die chip 108 is suctioned via a vacuum collet or air pincette or the like (not shown), the adhesive layer 103 and die attachment film 105 are peeled apart, and the die chip 108 having the die attachment film 105 attached thereto is picked-up.
(4) The die chip 108 having the die attachment film 105 attached thereto is mounted on the lead frame 111 or a circuit substrate. Then, the die attachment film 105 is heated, and the die chip 108 is thermally bonded to the lead frame 111 or a circuit substrate. Finally, the die chip 108 mounted on the lead frame 111 or the circuit substrate is molded via a resin (not shown).

A circuit substrate such as one formed of a circuit pattern may also be employed in the present production method instead of the lead frame 111.

### <Effects>

Hereinafter, the effects of the multi-layered adhesive sheet (die attachment film all-in-one sheet) 100 of the present embodiment will be described with reference to FIG. 1.

As shown in FIG. 1(1), the multi-layered adhesive sheet (die attachment film all-in-one sheet) 100 of the present embodiment includes: the substrate film 106, the adhesive layer 103 formed by coating the below-described adhesive onto this substrate film 106, and the die attachment film 105 laminated on top of the adhesive layer 103.

In addition, the abovementioned adhesive layer 103 is formed by coating an adhesive on the substrate film 106, the adhesive containing 100 parts by mass of an acrylic polymer and at least 0.5 parts by mass to no more than 20 parts by mass of a polyfunctional isocyanate curing agent, in which the acrylic polymer is formed by polymerization of a raw material composition obtained by compounding at least 90 parts by mass to no more than 99.9 parts by mass of a (meth)acrylic acid alkyl ester monomer having an alkyl group with at least 6 carbon atoms to no more than 12 carbon atoms, and at least 0.1 parts by mass to no more than 10 parts by mass of a functional group-containing monomer.

The multi-layered adhesive sheet (die attachment film all-in-one sheet) 100 employing the adhesive having the abovementioned construction is superior in retention of a die chip 108 during dicing of a silicon wafer 101, it is less likely that the multi-layered adhesive sheet 100 will come off from a ring frame 102 during dicing of the silicon wafer 101, and it easily allows for the peeling apart of the die attachment film 105 and the adhesive layer 103 during the pick-up operation of the die chip 108.

Moreover, the abovementioned adhesive may further contain a compound having at least one (meth)acryloyl group. Because the adhesiveness of the die attachment film 105 and the adhesive sheet 110 is further improved by having the abovementioned adhesive further contain a compound having at least one (meth)acryloyl group, the chip retention is further improved during dicing, and the peeling apart of the adhesive sheet 110 and the ring frame 102 is further prevented.

Thus, the production method for the electronic part employing this multi-layered adhesive sheet 100 allows for the pick-up of the die chip 108 with the die attachment film 105 attached to a rear surface of the die chip 108 after dicing of the silicon wafer 101, and the die chip 108 to be mounted and bonded as is on the lead frame 111 or the like.

Specifically, in the abovementioned production method for the electronic part, as shown in FIG. 1(1), the silicon wafer 101 is first pasted onto a surface of the die attachment film 105 of the multi-layered adhesive sheet 100 including: the substrate film 106, the adhesive layer 103 laminated onto this substrate film 106, and the abovementioned die attachment film 105 laminated on top of this adhesive layer 103.

Then, as shown in FIG. 1(2), the dicing of the silicon wafer 101 is performed with the silicon wafer 101 pasted onto the multi-layered adhesive sheet 100.

Next, as shown in FIG. 1(3), the picking-up of both the silicon wafer 101 and the die attachment film 105 attached to a rear surface of the silicon wafer 101 is performed, by peeling apart the die attachment film 105 and the adhesive layer 103 after the dicing.

According to such a method, because the adhesiveness between the adhesive layer 103 and the die attachment film 105 is strong enough during dicing and also the adhesiveness between the adhesive layer 103 and the ring frame 102 is strong enough during dicing, the retention of the die chip 108 during dicing is superior, and the multi-layered adhesive sheet 100 is less likely to come off from the ring frame 102 during dicing. On the other hand, because the adhesiveness between the adhesive layer 103 and the die attachment film 105 during the pick-up is minimized to a suitable strength, the die attachment film 105 and the adhesive layer 103 are easily peeled apart during the pick-up operation of the die chip 108.

Consequently, according to this method, as shown in FIG. 1(4), the die chip 108 can be picked up with the die attachment film 105 attached to a rear surface of the die chip 108 after dicing of the silicon wafer 101, and the die chip 108 can be mounted and bonded as is on the lead frame 111 or the like.

Although the embodiments of the present invention have been explained above with reference to the drawings, these are for illustrative purposes only, and thus various constructions other than those mentioned above may also be employed where necessary.

For example, although the silicon wafer 101 is used as the type of wafer in the abovementioned embodiment, any type of wafer may be employed (for example, a GAN wafer, etc.), without any particular limitations thereon. Regardless of the type of wafer, because the dicing blade 104 exists to properly cut such a wafer, a processing method for an electronic part similar to that of the abovementioned embodiment is feasible using the dicing blade 104, and the effects obtained therefrom similar even in such cases.

### Examples

Hereinafter, the present invention will be described in even greater detail by way of Examples. However, the present invention is not specifically limited to these Examples.

1. As the materials for the multi-layered adhesive sheet, the following were prepared.

Acrylic polymer A: A synthetic product, including a copolymer (acrylic polymer A) in which a raw material composition having a compounding ratio of 95% 2-ethylhexyl acrylate and 5% 2-hydroxy ethyl acrylate was copolymerized, was obtained. The glass transition point of the acrylic polymer A was −67.8° C.

Acrylic polymer B: A synthetic product, including a copolymer (acrylic polymer B) in which a raw material composition having a compounding ratio of 90% 2-ethylhexyl acrylate and 10% 2-hydroxy ethyl acrylate was copolymerized, was obtained. The glass transition point of the acrylic polymer B was −65.6° C.

Acrylic polymer C: A synthetic product, including a copolymer (acrylic polymer C) in which a raw material composition having a compounding ratio of 99.9% 2-ethylhexyl acrylate and 0.1% 2-hydroxy ethyl acrylate was copolymerized, was obtained. The glass transition point of the acrylic polymer C was −69.9° C.

Acrylic polymer D: A synthetic product, including a copolymer (acrylic polymer D) in which a raw material composition having a compounding ratio of 95% butyl acrylate and 5% 2-hydroxy ethyl acrylate was copolymerized, was obtained. The glass transition point of the acrylic polymer D was −53.3° C.

Polyfunctional isocyanate curing agent: A commercial product composed of 2,4-tolylene diisocyanate-trimethylol propane adduct (product name: Colonate L-45E, manufactured by Nippon Polyurethane Industry, Co., Ltd.) was employed.

Compound having one (meth)acryloyl group: A commercial product composed of 2-ethylhexyl acrylate (product name: Acrylic Acid Ester HA, manufactured by Toagosei, Co., Ltd.) was employed.

The adhesive was coated on a PET separator film until the thickness of the adhesive layer reached 10 μm after drying, this was then laminated on a 100 μm substrate film to obtain an adhesive sheet. A die attachment film with a thickness of 30 μm was cut into a circular shape with a diameter of 6.2 inches, and laminated onto the adhesive layer of the adhesive sheet to obtain the multi-layered adhesive sheet.

Ionomer resin: A commercial product manufactured by Du Pont-Mitsui Polychemicals Company, composed mainly of a Zn salt of an ethylene-methacrylic acid-methacrylic acid alkyl ester copolymer, having a MFR (melt flow rate) of 1.5 g/10 min (JIS K7210, 210° C.), a melting point of 96° C. and containing Zn²⁺ ions, was employed.

2. As the die attachment film, the following was prepared.

Die attachment film: A commercial product mainly composed of a polyimide adhesive, and having a thickness of 30 μm was employed.

3. As the electronic parts assembly, the following was prepared.

In the production of electronic parts, a silicon wafer on which a dummy circuit pattern was formed and having a diameter of six inches and a thickness of 0.4 mm was employed. The silicon wafer was placed on the die attachment film.

### <Dicing Process>

The depth of the incision into the adhesive sheet was 30 μm. The dicing was performed so as to be a chip size of 10 mm×10 mm. The dicing device that was employed was a DAD 341, manufactured by Disco Corporation. The dicing blade that was employed was an NBC-ZH2050-27HEEE, manufactured by Disco Corporation.
Dicing blade shape: An outer diameter of 55.56 mm, a blade thickness of 35 μm, and an inner diameter of 19.05 mm.
Dicing blade revolution number: 40,000 rpm.
Dicing blade feed rate: 80 mm/sec.
Cutting water temperature: 25° C.
Amount of cutting water: 1.0 L/min.

### <Expansion Process>

After the silicon wafer attached to the multi-layered adhesive sheet was diced, expansion was conducted using an expansion device.
Expansion device: HS-1800, manufactured by Hugle Electronics, Incorporated.
Expansion amount: 20 mm.
Expansion speed: 20 mm/sec.
Heating conditions: 40° C.×1 min.

### <Evaluation of Experimental Results>

1. Adhesion of the multi-layered pressure-sensitive adhesive sheet: A multi-layered adhesive sheet that was preheated to 80° C. was pasted on a silicon wafer, it was pressure bonded by rolling a 2 kg roller back and forth one time. The die attachment film and the adhesive sheet were peeled apart at an interface thereof one day after pressure bonding.
Peeling method: 180° peel.
Tensile speed: 300 mm/min.

2. Ring frame fixation: As shown in FIG. 2, an evaluation was conducted on the fixation of the ring frame during dicing of a semiconductor wafer. In cases where the adhesive sheet was not peeled from the ring, it was evaluated as being “⊚ (Superior)”; in cases where a portion was confirmed as hanging therefrom, it was evaluated as being “◯ (Good)”; and in cases where it was confirmed as being peeled, it was evaluated as being “× (Unacceptable)”. The results thereof are indicated in Tables 1 to 3.

3. Chip retention: As shown in FIG. 3, an evaluation was conducted on the number of chips retained in the multi-layered adhesive sheet, when a semiconductor wafer was diced under the abovementioned conditions. The results thereof are indicated in Tables 1 to 3.
⊚ (Superior): Chip scattering was less than 5%.
◯ (Good): Chip scattering was at least 5% to less than 10%.
× (Unacceptable): Chip scattering was at least 10%.

4. Pick-up: As shown in FIG. 4, an evaluation was conducted on the number of chips with the die attachment film attached thereto that could be picked-up, after a semiconductor wafer was diced under the abovementioned conditions. The results thereof are indicated in Tables 1 to 3.
⊚ (Superior): At least 95% of the chips could be picked-up.
◯ (Good): At least 80% to less than 95% of the chips could be picked-up.
× (Unacceptable): Less than 80% of the chips could be picked-up.

TABLE 1

| | | Experimental No. | | | | |
|---|---|---|---|---|---|---|
| | | 1 | 2 | 3 | 4 | 5 |
| Adhesive | Acrylic polymer | A 100 | A 100 | A 100 | A 100 | A 100 |
| (type and parts | Polyfunctional isocyanate curing | 5 | 0.1 | 0.5 | 20 | 50 |
| by mass) | agent | | | | | |
| | Compound having one | 0.01 | 0.01 | 0.01 | 0.01 | 0.01 |
| | (meth)acryloyl group | | | | | |
| Adhesiveness | with respect to a die attachment film | 0.22 | 1.00 | 0.40 | 0.10 | 0.05 |
| of | (N/20 mm) | | | | | |
| adhesive sheet | | | | | | |
| Evaluation | Ring frame fixation | ⊚ | ⊚ | ⊚ | ◯ | ⊚ |
| | Chip retention | ⊚ | ⊚ | ⊚ | ◯ | ⊚ |
| | Pick-up | ⊚ | ◯ | ◯ | ⊚ | ◯ |

| | | | | | |
|---|---|---|---|---|---|
| Remarks | Example | Example | Example | Example | Example |

TABLE 2

| | | Experimental No. | | | | |
|---|---|---|---|---|---|---|
| | | 1 | 6 | 7 | 8 | 9 |
| Adhesive | Acrylic polymer | A 100 | A 100 | A 100 | A 100 | A 100 |
| (type and parts | Polyfunctional isocyanate curing | 5 | 5 | 5 | 5 | 5 |
| by mass) | agent | | | | | |
| | Compound having one | 0.01 | 0 | 0.005 | 0.1 | 0.5 |
| | (meth)acryloyl group | | | | | |
| Adhesiveness | with respect to a die attachment film | 0.22 | 0.20 | 0.21 | 0.35 | 0.50 |
| of | (N/20 mm) | | | | | |
| adhesive sheet | | | | | | |
| Evaluation | Ring frame fixation | ⊚ | ⊚ | ⊚ | ⊚ | ⊚ |
| | Chip retention | ⊚ | ⊚ | ⊚ | ⊚ | ⊚ |
| | Pick-up | ⊚ | ⊚ | ⊚ | ◯ | ◯ |

| | | | | | |
|---|---|---|---|---|---|
| Remarks | Example | Example | Example | Example | Example |

TABLE 3

| | | Experimental No. | | | |
|---|---|---|---|---|---|
| | | 1 | 10 | 11 | 12 |
| Adhesive | Acrylic polymer | A 100 | B 100 | C 100 | D 100 |
| (type and parts | Polyfunctional isocyanate curing agent | 5 | 5 | 5 | 5 |
| by mass) | Compound having one (meth)acryloyl | 0.01 | 0.01 | 0.01 | 0.01 |
| | group | | | | |
| Adhesiveness | with respect to a die attachment film | 0.22 | 0.38 | 0.50 | 0.70 |
| of | (N/20 mm) | | | | |
| adhesive sheet | | | | | |
| Evaluation | Ring frame fixation | ⊚ | ⊚ | ⊚ | ⊚ |
| | Chip retention | ⊚ | ⊚ | ⊚ | ⊚ |
| | Pick-up | ⊚ | ◯ | ◯ | X |

| | | | | |
|---|---|---|---|---|
| Remarks | Example | Example | Example | Comparative |
| | | | | Example |

Moreover, in Tables 1 to 3 parts by mass is indicated with respect to 100 parts by mass of acrylic polymer. In addition, the letters A to D indicate the type of acrylic polymer.

### <Experimental Discussion>

As understood from the experimental results indicated in Tables 1 to 3, according to the present multi-layered adhesive sheet (die attachment film all-in-one sheet), because the adhesive having the specific composition is employed, chip retention during dicing is superior, the multi-layered adhesive sheet is less likely to come off from the ring frame during dicing and the die attachment film and the adhesive layer are easily peeled apart during the pick-up operation.

While the present invention has been described with reference to examples, it is understood that these examples are for illustrative purposes only, various modifications are possible, and such modifications are within the scope of the invention.

### INDUSTRIAL APPLICABILITY

As described above, the abovementioned multi-layered adhesive sheet achieves the effects of superior chip retention during dicing, it is less likely to come off from a ring frame during dicing and it allows a die attachment film and an adhesive layer to be easily peeled apart during the pick-up operation. Consequently, the abovementioned multi-layered adhesive sheet is preferably employed in a production method for an electronic part, in which a chip with the die attachment film attached to a rear surface thereof is picked-up after dicing, and mounted and bonded as is on a lead frame or the like.

1. An adhesive comprising 100 parts by mass of an acrylic polymer and at least 0.5 parts by mass to no more than 20 parts by mass of a polyfunctional isocyanate curing agent, said acrylic polymer being formed by polymerization of a raw material composition obtained by compounding at least 90 parts by mass to no more than 99.9 parts by mass of a (meth)acrylic acid alkyl ester monomer having an alkyl group with at least 6 carbon atoms to no more than 12 carbon atoms and at least 0.1 parts by mass to no more than 10 parts by mass of a functional group-containing monomer.

2. The adhesive according to claim 1, further comprising a compound having at least one (meth)acryloyl group.

3. An adhesive sheet comprising a substrate film and an adhesive layer formed by coating the adhesive of claim 1 on said substrate film.

4. A multi-layered adhesive sheet comprising the adhesive sheet of claim 3 and a die attachment film laminated on said adhesive layer side of said adhesive sheet.

5. A production method for an electronic part obtained by dicing a wafer, comprising the steps of pasting a wafer on a surface of said die attachment film of the multi-layered sheet of claim 4; dicing said wafer with it pasted to said multi-layered adhesive sheet; and picking-up both said wafer and the die attachment film attached to a rear surface of said wafer, by peeling apart said die attachment film and said adhesive layer after the dicing.
